(19) United States
(12) Patent Application Publication
(10) Pub. No.: US 2013/0049015 A1
(43) Pub. Date: Feb. 28, 2013

(54) LEDS AND METHODS FOR MANUFACTURING THE SAME

(71) Applicants: Kuo-Lung Fang, Zhudong Township (TW); Jui-Yi Chu, Taichung City (TW)

(72) Inventors: Kuo-Lung Fang, Zhudong Township (TW); Jui-Yi Chu, Taichung City (TW)

(73) Assignee: LEXTAR ELECTRONICS CORPORATION, Hsinchu (TW)

(21) Appl. No.: 13/591,721

(22) Filed: Aug. 22, 2012

(30) Foreign Application Priority Data
Aug. 23, 2011 (TW) 100130065

(51) Int. Cl. H01L 33/02

(52) U.S. Cl. 257/79; 438/42; 257/E33.005

(57) ABSTRACT

A light emitting diode (LED) is disclosed. The LED includes a substrate, a first semiconductor layer, an active layer, a second semiconductor layer, and a patterned structure. The first semiconductor layer having first and second regions is positioned on the substrate, wherein the first region is thicker than the second region. The active layer is positioned on the first region of the first semiconductor layer. The second semiconductor layer is positioned on the active layer, wherein the first and second semiconductor layers have opposite conductivities. The patterned structure is formed on a sidewall of the first region of the first semiconductor layer or on a sidewall of the second semiconductor layer.

This application claims the benefit of Taiwan application Serial No. 100130065, filed Aug. 23, 2011, the subject matter of which is incorporated herein by reference.

### BACKGROUND OF THE INVENTION

1. Field of the Invention

The invention relates in general to light emitting diode (LED), and more particularly to a sidewall structure thereof.

2. Description of the Related Art

As shown in FIG. 1, a light emitting diode (LED) chip is usually formed of a substrate 10, a semiconductor layer 11, an active layer 13, and a semiconductor layer 15 stacked together, having an even sidewall surface. The semiconductor layers 11 and 15 have opposite conductivities. The semiconductor layers 11 and 15 respectively have a solder pad 17 for electrically connecting to an external circuit. The even sidewall surface makes a light emitted by the active layer 13 fully reflected, hence deteriorating the light extraction efficiency of the LED chip. To resolve the above problems, an undercut LED chip as shown in FIG. 2 can be formed by a dry etching process or a wet etching process. Despite the undercut structure, which is wide at the top and narrow at the bottom, may increase the light extraction efficiency for the LED chip, the formation of the undercut structure may damage a part of the active layer 13 and accordingly deteriorate element efficiency.

Therefore, a new LED chip structure and a corresponding manufacturing method are needed to resolve the problem of full reflection caused by an even sidewall surface.

### SUMMARY OF THE INVENTION

According to an embodiment of the present invention, a method of manufacturing a light emitting diode is provided. The method includes the following steps. A first semiconductor layer, an active layer, and a second semiconductor layer are sequentially formed on a substrate, wherein the first and second semiconductor layers have opposite conductivities. A groove penetrating through the second semiconductor layer, the active layer, and a part of the first semiconductor layer is formed to define a stacked structure in-between the groove. A planarization layer is formed on the first and second semiconductor layers to fill up the groove. A hard mask pattern is formed on the planarization layer, wherein the hard mask pattern has a full mask area and a partial mask area corresponding to the groove. An oblique ion implantation penetrating through the partial mask area is preformed to form a patterned doped region on a sidewall of the first semiconductor layer or on a sidewall of the second semiconductor layer. The hard mask pattern and the planarization layer are removed. The patterned doped region is removed to form a patterned structure on the sidewall of the first semiconductor layer or on the sidewall of the second semiconductor layer.

According to another embodiment of the present invention, a light emitting diode (LED) is provided. The LED includes a substrate, a first semiconductor layer, an active layer, a second semiconductor layer, and a patterned structure. The first semiconductor layer having a first region and a second region is positioned on the substrate, wherein a thickness of the first region is larger than a thickness of the second region. The active layer is positioned on the first region of the first semiconductor layer. The second semiconductor layer is positioned on the active layer, wherein the first and second semiconductor layers have opposite conductivities. The patterned structure is formed on a sidewall of the first region of the first semiconductor layer or on a sidewall of the second semiconductor layer.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIGS. 1˜2 are cross-sectional views of a light emitting diode according to prior art.

FIGS. 3A, 4A, 5A, 6A, 7A, 8A, 9A-9B, 10A-10D, 11, 12A-12B, and 13A-13D are cross-sectional views of a manufacturing process of a light emitting diode according to an embodiment of the disclosure; and

FIGS. 3B, 4B, 5B, 6B, 7B, and 8B are top views of the structures as shown in FIGS. 3A, 4A, 5A, 6A, 7A, and 8A.

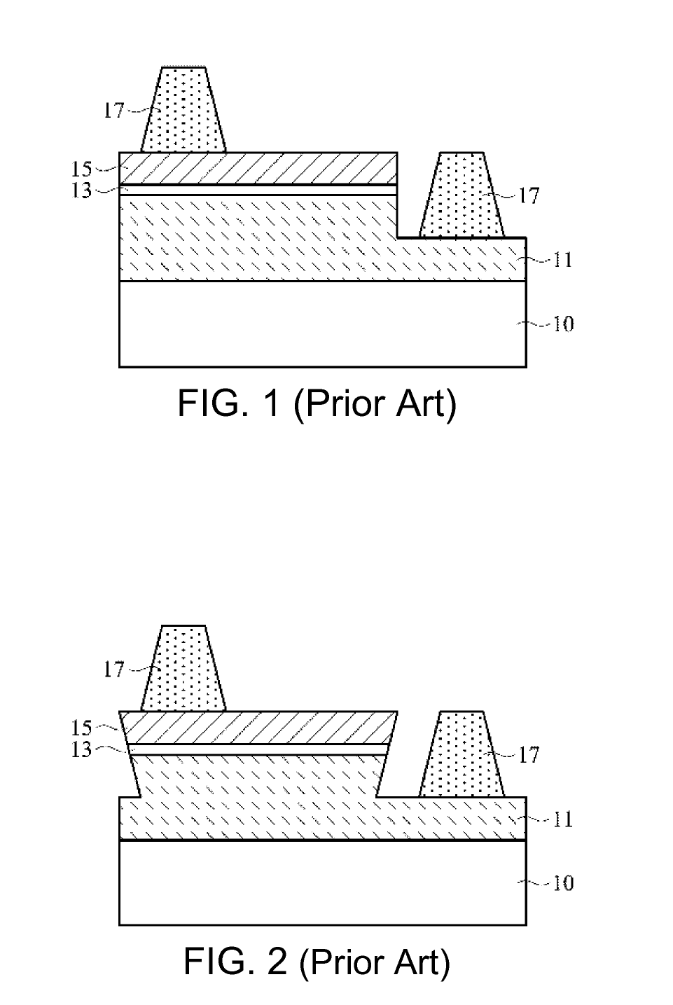

### DETAILED DESCRIPTION OF THE INVENTION

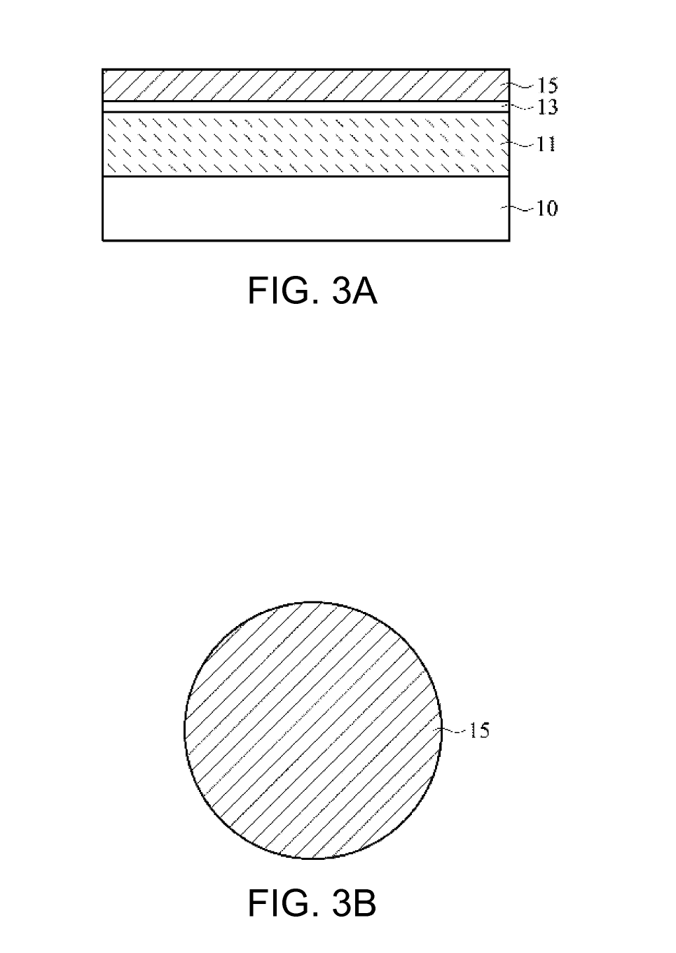

As shown in FIG. 3A, a substrate 10, which can be a sapphire substrate, a silicon substrate, or a silicon carbide substrate, is provided. Then, a semiconductor layer 11, an active layer 13, and a semiconductor layer 15 are sequentially formed on the substrate 10 by such as an epitaxial process. The semiconductor layers 11 and 15 have opposite conductivities. When the semiconductor layer 11 is an n-type semiconductor layer, the semiconductor layer 15 is a p-type semiconductor layer, and vice versa. In an embodiment of the disclosure, the semiconductor layer 11 is an n-type GaN layer, the semiconductor layer 15 is a p-type GaN layer, and the active layer 13 is a multiple quantum well (MQW) formed of InGaN/GaN. In other embodiments, the semiconductor layers 11 and 15 and the active layer 13 may be formed of other materials, and are not limited to the above-mentioned materials. The thickness of the semiconductor layer 11 may be larger than, equal to, or smaller than that of the semiconductor layer 15. In an embodiment of the disclosure, the n-type semiconductor layer 11 is thinner than the p-type semiconductor layer 15. A top view of the structure of FIG. 3A is shown in FIG. 3B.

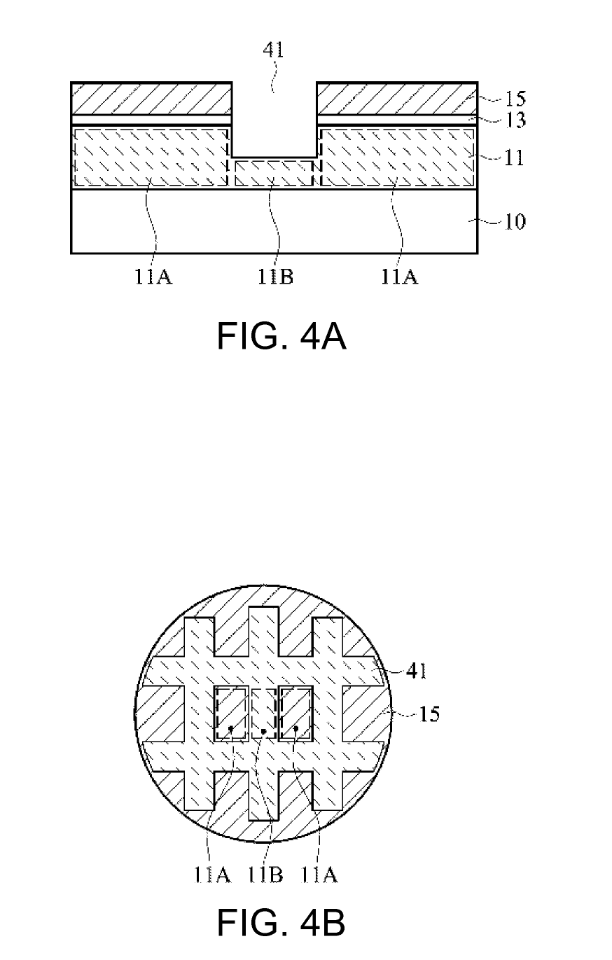

Then, as shown in FIG. 4A, a groove 41 penetrating through the semiconductor layer 15, the active layer 13, and a part of the semiconductor layer 11 is formed to define a stacked structure in-between the groove 41. The groove 41 may be formed by lithography combined with an etching process. For example, a mask layer (not shown) is first formed on the semiconductor layer 15, and then a photo-resist pattern is formed on the mask layer by lithography. Then, the mask layer not protected by the photo-resist pattern is removed first, and the semiconductor layer 15 not protected by the mask layer, the active layer 13, and the part of the semiconductor layer 11 are removed next. The etching process is preferably a non-isotropic etching process, such as a dry etching process using plasma. Thus, the stacked structure has an even sidewall, and the undercut damage to the active layer 13 is avoided. A top view of the structure of FIG. 4A is shown in FIG. 4B. As shown in FIGS. 4A and 4B, the semiconductor layer 11 has a first portion 11A and a second portion 11B, wherein the first portion 11A is a part of the stacked structure, and the second portion 11B is exposed from the groove 41. Although a top view of the first portion 11A shows that the first portion 11A is a rectangle, the shape of the first portion 11A may also be a square, a diamond, or other shapes according to actual needs.

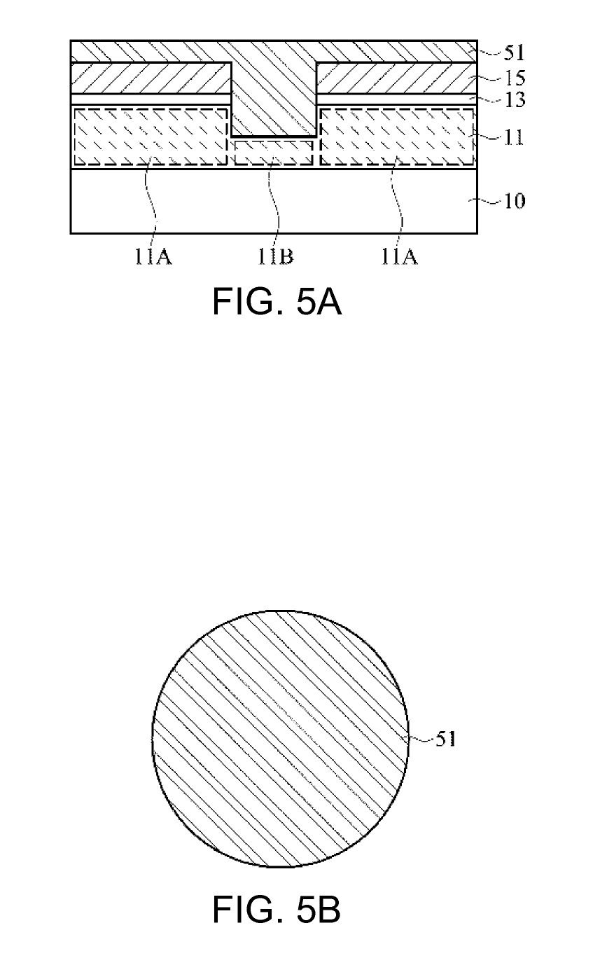

Then, as shown in FIG. 5A, a planarization layer 51 having an even top surface is formed on the structure as shown in FIG. 4A. In an embodiment of the disclosure, the planarization layer 51 may be benzocyclobutene (BCB) resin, such as non-photosensitive BCB resin formed by a spin coating process. A top view of the structure of FIG. 5A is shown in FIG. 5B.

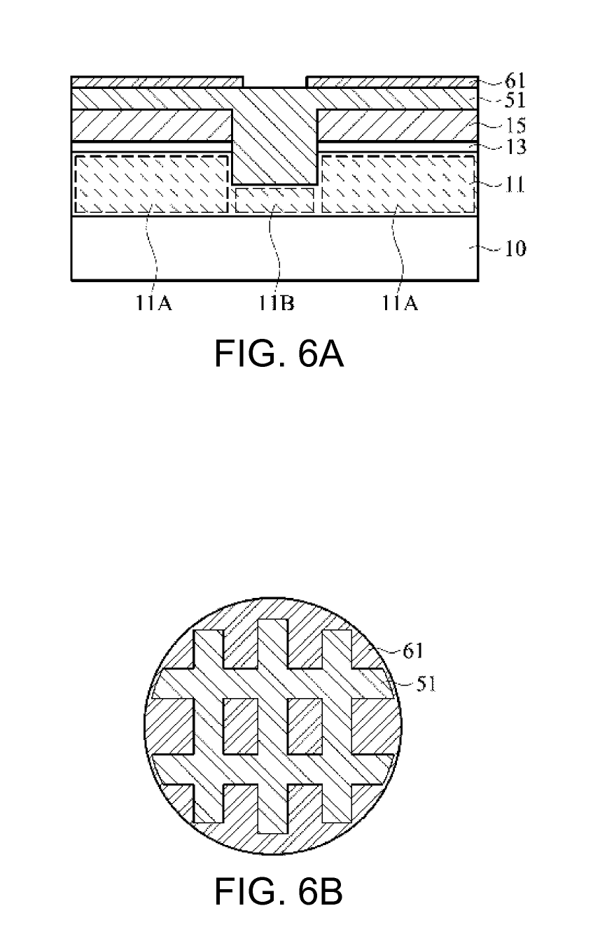

Then, as shown in FIG. 6A, a hard mask pattern 61 is formed on the planarization layer 51. The hard mask pattern 61 has a full mask area and an opening area corresponding to the groove 41. Details of a method of forming the hard mask pattern 61 are as follows. After an entire layer of a hard mask (not shown), such as a metal mask, a photo-resist, an oxide such as silica or zinc oxide, or a nitride such as silicon nitride, is formed, a photo-resist pattern is formed on the hard mask layer by lithography. Then, the hard mask layer not covered by the photo-resist pattern is removed, and the hard mask pattern 61 is formed accordingly. A top view of the structure of FIG. 6A is shown in FIG. 6B.

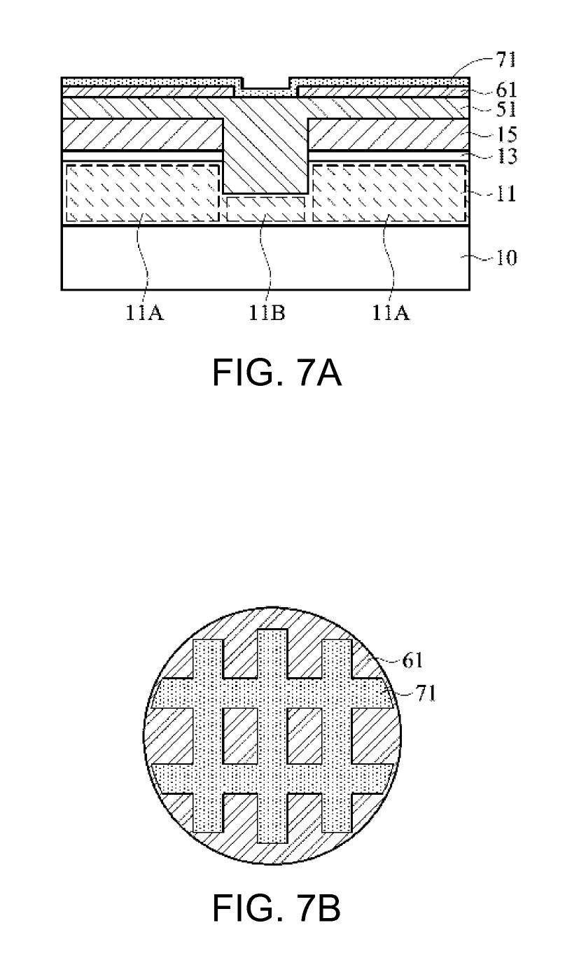

Then, as shown in FIG. 7A, a metal film 71 is formed on the hard mask pattern 61 and the exposed planarization layer 51. The metal film 71 may be made from nickel or platinum and formed by a sputtering process, and the thickness of the metal film 71 is about 5 nm˜100 nm. If the metal film 71 is too thick, then a non-periodic pattern cannot be formed by a tempering process. If the metal film 71 is too thin, then the density of the non-periodic pattern formed by the tempering process is too little. A top view of the structure of FIG. 7A is shown in FIG. 7B.

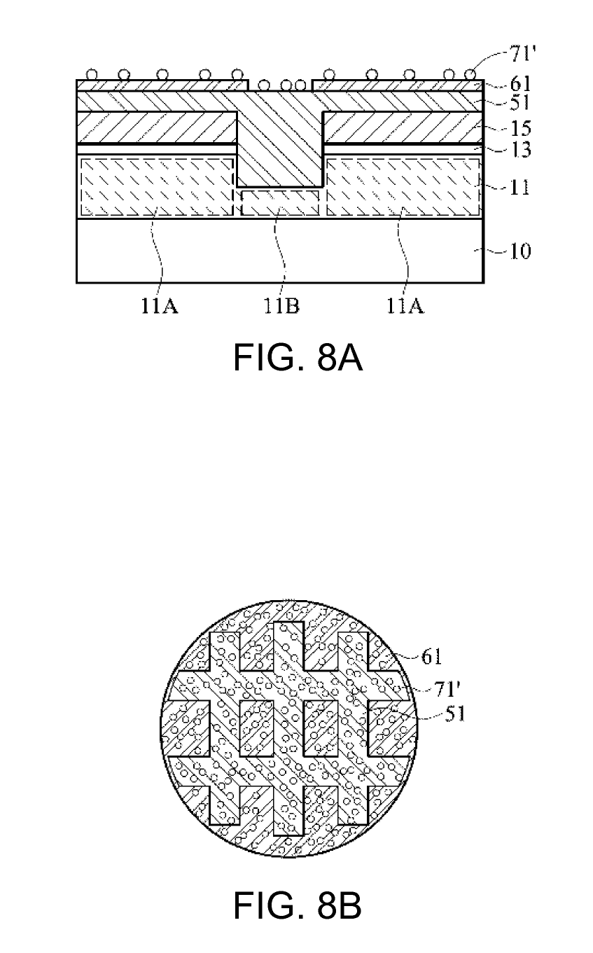

Then, as shown in FIG. 8A, the tempering process is performed, such that the metal film 71 turns into a non-periodic mask 71′. The non-periodic mask 71′ is disposed on the opening area of the hard mask pattern 61 and may be used as a partial mask area. In an embodiment of the disclosure, the temperature of the tempering process is about 300° C.˜1000° C., and the tempering time is 10˜300 seconds. If the tempering temperature is too high and/or the tempering time is too long, then the metal film may be over baked. If the tempering temperature is too low and/or the tempering time is too short, then the non-periodic pattern cannot be formed. A top view of the structure of FIG. 8A is shown in FIG. 8B.

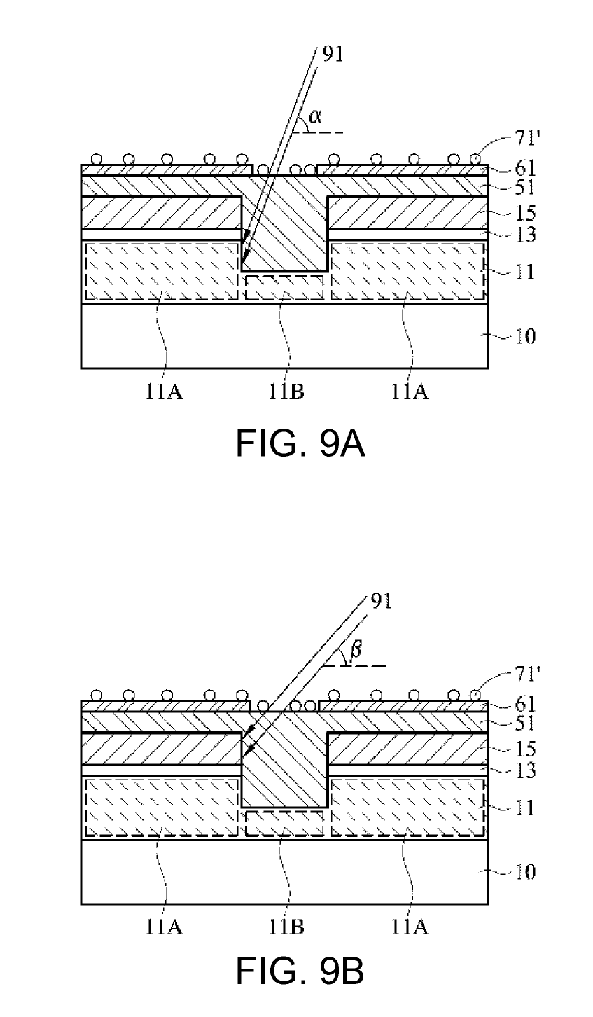

Then, as shown in FIG. 9A, an oblique ion implantation 91 is performed on the structure as shown in FIG. 8A. The oblique ion implantation 91 penetrates through the non-periodic mask 71′, such that a sidewall of the first portion 11A of the semiconductor layer 11 forms a non-periodic doped region. In an embodiment of the disclosure, to avoid the oblique ion implantation 91 affecting the active layer 13, the width of the non-periodic mask 71′ used as the partial mask area (or the width of the opening area of the hard mask pattern 61) is preferably smaller than the width of the groove 41. In an embodiment of the disclosure, argon ions or oxygen ions may be used as doping materials for the oblique ion implantation 91, and the oblique angle α may be 5°˜40°. If the oblique implantation angle α is too small, then the active layer 13 may have a doped region. If the oblique implantation angle α is too large, then the doped region may be formed on a top surface of the second portion 11B of the semiconductor layer 11, and may not be formed on the sidewall of the first portion 11A of the semiconductor layer 11.

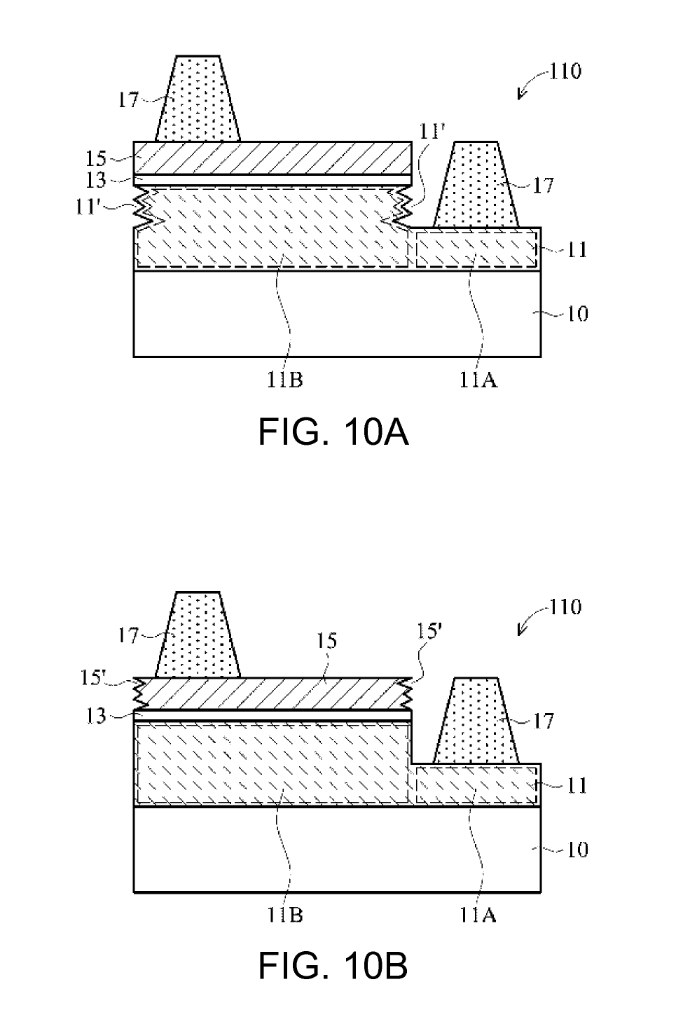

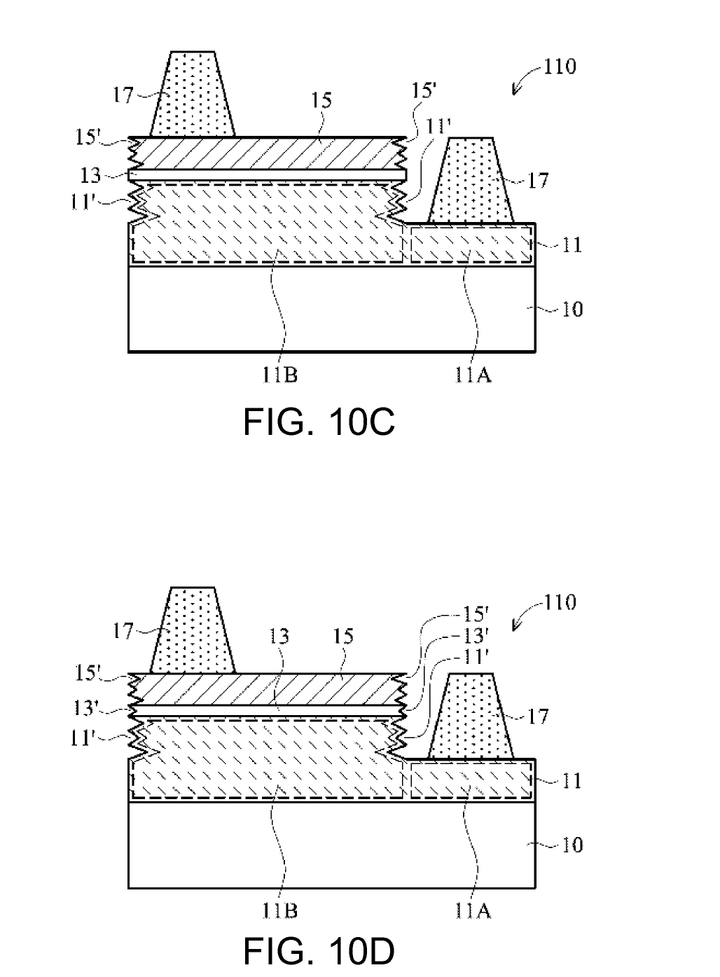

Then, as shown in FIG. 10A, the non-periodic mask 71′, the hard mask pattern 61, the planarization layer 51, and the doped region of the semiconductor layer 11 are removed to form a non-periodic patterned structure 11′ on the sidewall of the first portion 11A of the semiconductor layer 11. Then, a solder pad 17 is formed on a second portion 11B of the semiconductor layer 11 and on a top surface of the semiconductor layer 15 to be electrically connected to an external circuit. Lastly, the entire wafer may be divided into individual grains, and the LED 110 is formed accordingly. The non-periodic mask 71′ may be removed by a wet etching process using an acid or alkali solution, by a dry etching process using inductively coupled plasma (ICP) or reactive ion etching (RIE), or by a combination thereof. The hard mask pattern 61 may be removed by a wet etching process using an acid or alkali solution, by a dry etching process using ICP or RIE, or by a combination thereof. The planarization layer 51 may be removed by a wet etching process using an acid or alkali solution. The doped region of the semiconductor layer 11 may be removed by a dry etching process using ICP or RIE or by a combination thereof. It is noted that the said oblique ion implantation 91 will deteriorate the lattice of the doped region. Therefore, under the circumstance that the non-doped semiconductor layer 15 and a sidewall of the active layer 13 are not greatly affected, the doped region may be completely removed to form the non-periodic patterned structure 11′.

In another embodiment of the disclosure, as shown in FIG. 9B, the oblique ion implantation 91 is performed on the structure as shown in FIG. 8A. The oblique ion implantation 91 penetrates through the non-periodic mask 71′, such that a sidewall of the semiconductor layer 15 forms a non-periodic doped region. In an embodiment of the disclosure, to avoid the oblique ion implantation 91 affecting the active layer 13, the width of the non-periodic mask 71′ used as a partial mask area (or the width of the opening area of the hard mask pattern 61) is preferably smaller than the width of the groove 41. In an embodiment of the disclosure, argon ions or oxygen ions may be used as doping materials for the oblique ion implantation 91, and the oblique angle β may be 5°˜40°. If the oblique implantation angle β is too small, then the top surface of the semiconductor layer 15 may have a doped region. If the oblique implantation angle β is too large, then the active layer 13 may have a doped region. It is understood that the oblique angles α and β of the oblique ion implantation 91 as shown in FIGS. 9A and 9B are determined according to the width of the opening area of the hard mask pattern 61, the thickness of the semiconductor layer 15, and the height of the sidewall of the first portion 11A of the semiconductor layer 11. It is noted that the oblique angle α of the oblique ion implantation 91 as shown in FIG. 9A must be larger than the oblique angle β of the oblique ion implantation 91 as shown in FIG. 9B.

Then, as shown in FIG. 10B, the non-periodic mask 71′, the hard mask pattern 61, the planarization layer 51, and the doped region of the semiconductor layer 15 are removed, and a non-periodic patterned structure 15′ is formed on the sidewall of the semiconductor layer 15. Then, the solder pad 17 is formed on the second portion 11B of the semiconductor layer 11 and on the top surface of the semiconductor layer 15 to be electrically connected to an external circuit. Lastly, the entire wafer is divided into individual grains, and the LED 110 is formed accordingly. The details of removing the non-periodic mask 71′, the hard mask pattern 61, the planarization layer 51, and the doped region of the semiconductor layer 15 are already disclosed as above-mentioned and are not repeated here. It is noted that the oblique ion implantation 91 will deteriorate the lattice of the doped region. Therefore, under the circumstance that the non-doped semiconductor layer 11 and the sidewall of the active layer 13 are not greatly affected, the doped region may be completely removed to form the non-periodic patterned structure 15′.

It is understood that after the oblique ion implantation 91 as shown in FIG. 9A (or FIG. 9B) is performed, the oblique ion implantation 91 as shown in FIG. 9B (or FIG. 9A) may be performed, such that the sidewalls of the semiconductor layers 11 and 15 both have a doped region. Thus, after the non-periodic mask 71′, the hard mask pattern 61, the planarization layer 51, and the doped regions of the semiconductor layers 11 and 15 are removed, the non—the periodic patterned structures 11′ and 15′ may be formed on the sidewalls of the semiconductor layers 11 and 15 as shown in FIG. 10C.

In another embodiment of the disclosure, the width of the non-periodic mask 71′ (or the width of the opening area of the hard mask pattern 61) and the width of the groove 41 are substantially the same. Meanwhile, the oblique ion implantation 91 may be performed once such that the semiconductor layer 11, the active layer 13, and the active layer 15 all have a non-periodic doped region. Thus, after the non-periodic mask 71′, the hard mask pattern 61, the planarization layer 51, and the doped regions of the semiconductor layers 11 and 15 and the active layer 13 are removed, the non-periodic patterned structures 11′, 13′, and 15′ may be formed on the sidewalls of the semiconductor layer 11, the active layer 13, and the semiconductor layer 15, as shown in FIG. 10D. It is noted that the pattern of the doped region is determined according to the pattern of the non-periodic mask 71′. In other words, the non-periodic patterned structures 11′ and 15′ correspond to the pattern of the non-periodic mask 71′.

As described above, the top view of the first portion 11A of the semiconductor layer 11 and the semiconductor layer 15 may be a rectangle as shown in FIG. 4B. In an embodiment of the disclosure, the non-periodic structure 11′ (and/or 15′) is formed on the four sides of the rectangular first portion 11A. In another embodiment of the disclosure, the non-periodic structure 11′ (and/or 15′) is only formed on a long side of the rectangular first portion 11A and not formed on a short side of the rectangular first portion 11A, so that the cost of forming the non-periodic structure 11′ (and/or 15′) on the short side of the rectangle is reduced. As the ratio of the long side vs. the short side of the rectangular first portion 11A grows bigger, the above-mentioned method of forming the non-periodic structure 11′ (and/or 15′) on the long side of the rectangle saves more cost, and the light extraction efficiency is less likely to deteriorate.

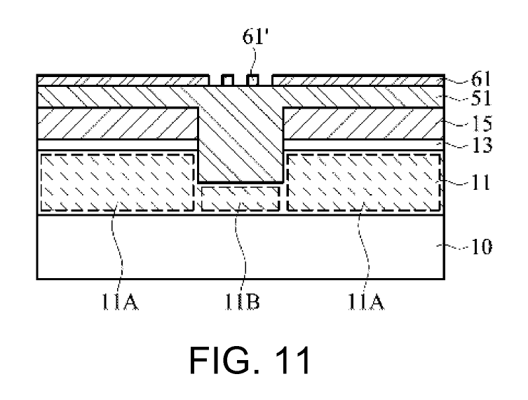

In other embodiments of the disclosure, the hard mask pattern 61 formed on the planarization layer 51 comprises a full mask area and a partial mask area (such as the periodic mask 61′) corresponding to the groove 41 as shown in FIG. 11. In an embodiment of the disclosure, the pattern of the periodic mask 61 may be a grating. Details of a method of forming the hard mask pattern 61 are as follows. After an entire layer of a hard mask (not shown), such as a metal mask, a photo-resist, an oxide such as silica or zinc oxide, or a nitride such as silicon nitride, is formed, a photo-resist pattern is formed on the hard mask layer by lithography. Then, the hard mask layer not covered by the photo-resist pattern is removed, and the hard mask pattern 61 is formed accordingly.

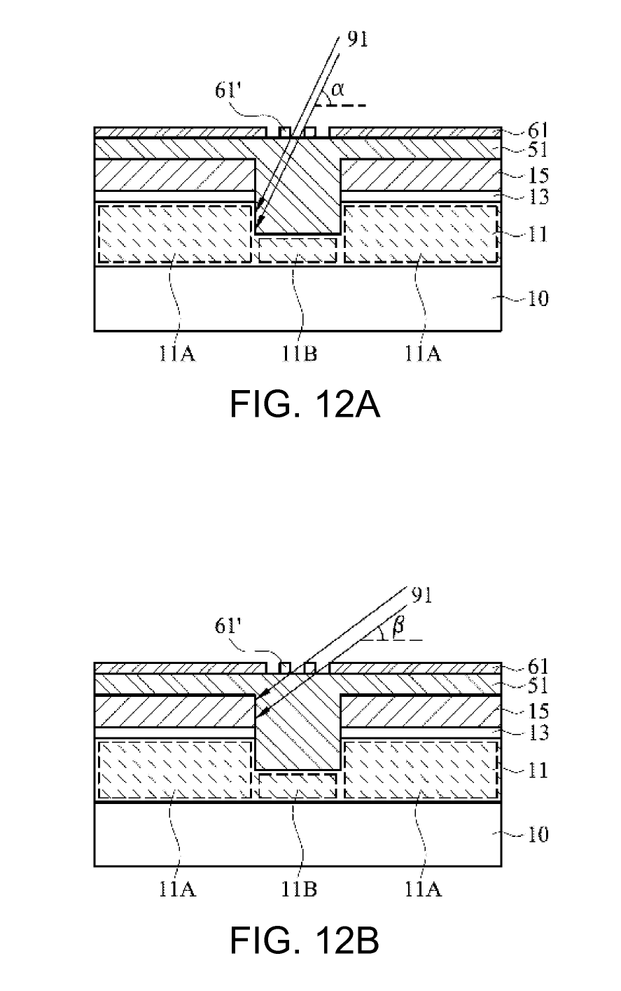

Then, as shown in FIG. 12A, the oblique ion implantation 91 is performed on the structure as shown in FIG. 11. The oblique ion implantation 91 penetrates through the periodic mask 61′, such that the sidewall of the first portion 11A of the semiconductor layer 11 forms a periodic doped region. In an embodiment of the disclosure, to avoid the oblique ion implantation 91 affecting the active layer 13, the width of the periodic mask 61′ used as a partial mask area is preferably smaller than the width of the groove 41. In an embodiment of the disclosure, argon ions or oxygen ions may be used as doping materials for the oblique ion implantation 91, and the oblique angle α is between 5°˜40°. If the oblique implantation angle α is too small, then the active layer 13 may have a doped region. If the oblique implantation angle α is too large, then the doped region will be formed on the top surface of the second portion 11B of the semiconductor layer 11 and not formed on the sidewall of the first portion 11A of the semiconductor layer 11.

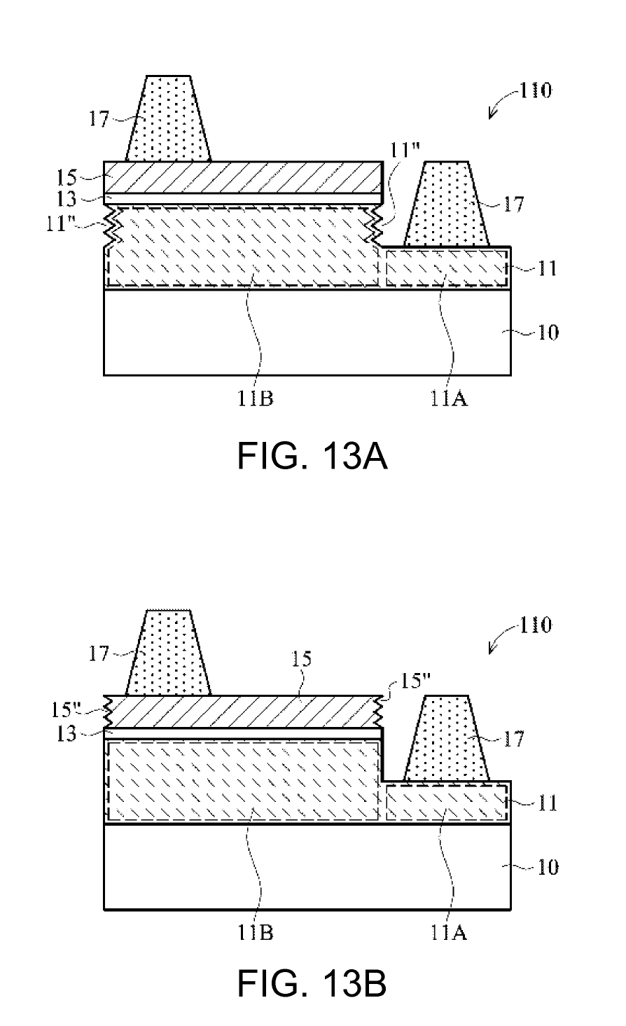

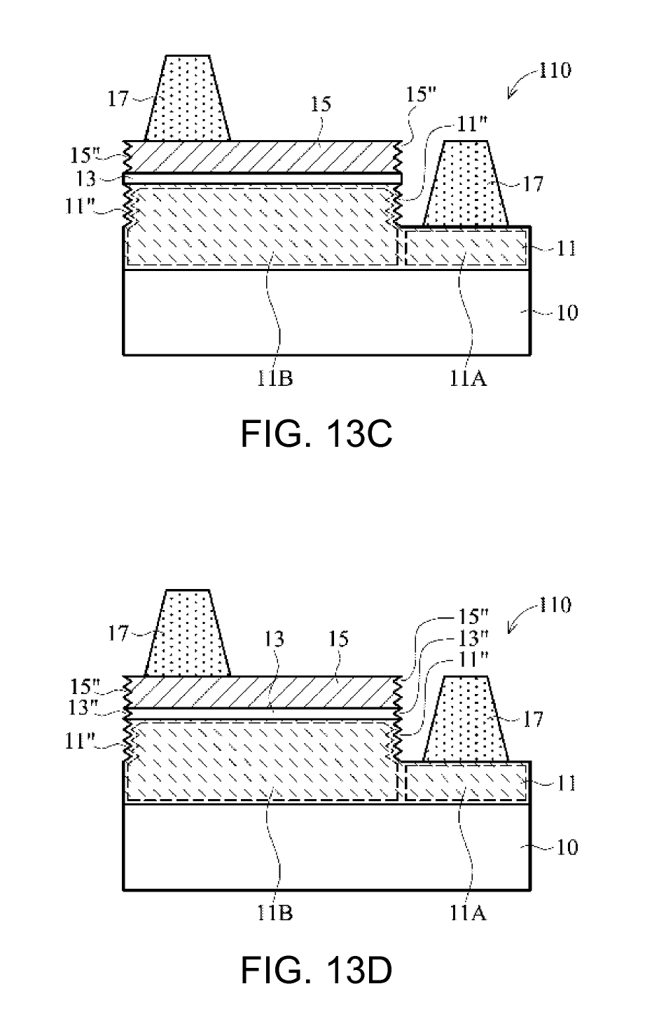

Then, as shown in FIG. 13A, the hard mask pattern 61 with the periodic mask 61′, the planarization layer 51, and the periodic doped region of the semiconductor layer 11 are removed, and a periodic patterned structure 11″ is formed on the sidewall of the first portion 11A of the semiconductor layer 11. Then, the solder pad 17 is formed on the second portion 11B of the semiconductor layer 11 and on the top surface of the semiconductor layer 15 to be electrically connected to an external circuit. Lastly, the entire wafer is divided into individual grains, and the LED 110 is formed accordingly. The details of removing the hard mask pattern 61 with the periodic mask 61′, the planarization layer 51, and the doped region of the semiconductor layer 11 are already disclosed as above-mentioned and are not repeated here. It is noted that the oblique ion implantation 91 will deteriorate the lattice of the doped region. Therefore, under the circumstance that the non-doped semiconductor layer 15 and the sidewall of the active layer 13 are not greatly affected, the doped region may be completely removed to form the periodic patterned structure 11″.

In another embodiment of the disclosure, as shown in FIG. 12B, the oblique ion implantation 91 is performed on the structure as shown in FIG. 11. The oblique ion implantation 91 penetrates through the periodic mask 61′, such that the sidewall of the semiconductor layer 15 forms a periodic doped region. In an embodiment of the disclosure, to avoid the oblique ion implantation 91 affecting the active layer 13, the width of the periodic mask 61′ used as a partial mask area is preferably smaller than the width of the groove 41. In an embodiment of the disclosure, argon ions or oxygen ions may be used as doping materials, and the oblique angle β is between 5°˜40°. If the oblique implantation angle β is too small, then the top surface of the semiconductor layer 15 may have a doped region. If the oblique implantation angle β is too large, then the active layer 13 may have a doped region. It is understood that the oblique angles α and β of the oblique ion implantation 91 as shown in FIGS. 12A and 12B are determined according to the width of the opening area of the hard mask pattern 61, the thickness of the semiconductor layer 15, and the height of the sidewall of the first portion 11A of the semiconductor layer 11. It is noted that the oblique angle α of the oblique ion implantation 91 as shown in FIG. 9A must be larger than the oblique angle β of the oblique ion implantation 91 as shown in FIG. 9B.

Then, as shown in FIG. 13B, the hard mask pattern 61 with the periodic mask 61′, the planarization layer 51, and the doped region of the semiconductor layer 15 are removed, and a periodic patterned structure 15″ is formed on the sidewall of on the semiconductor layer 15. Then, the solder pad 17 is formed on the second portion 11B of the semiconductor layer 11 and on the top surface of the semiconductor layer 15 to be electrically connected to an external circuit. Lastly, the entire wafer is divided into individual grains, and the LED 110 is formed accordingly. The details of removing the hard mask pattern 61 with the periodic mask 61′, the planarization layer 51, and the doped region of the semiconductor layer 15 are already disclosed as above-mentioned and are not repeated here. It is noted that the oblique ion implantation 91 will deteriorate the lattice of the doped region. Therefore, under the circumstance that the non-doped semiconductor layer 11 and the sidewall of the active layer 13 are not greatly affected, the doped region may be completely removed to form the periodic patterned structure 15″.

It is understood that after the oblique ion implantation 91 as shown in FIG. 12A (or FIG. 12B), the oblique ion implantation 91 as shown in FIG. 12B (or FIG. 12A) may be performed, such that the sidewalls of the semiconductor layers 11 and 15 both have a doped region. Thus, after the hard mask pattern 61 with the periodic mask 61′, the planarization layer 51, and the doped regions of the semiconductor layers 11 and 15 are removed, the periodic patterned structures 11″ and 15″ may be formed on the sidewalls of the semiconductor layers 11 and 15, as shown in FIG. 13C.

In another embodiment of the disclosure, the width of the periodic mask 61′ and the width of the groove 41 are substantially the same. Meanwhile, the oblique ion implantation 91 may be performed once such that the semiconductor layer 11, the active layer 13, and the active layer 15 all have a non-periodic doped region. Thus, after the hard mask pattern 61 with the periodic mask 61′, and the doped regions of the semiconductor layers 11 and 15 and the active layer 13 are removed, the periodic patterned structures 11″, 13″, and 15″ may be formed on the sidewalls of the semiconductor layer 11, the active layer 13, and the semiconductor layer 15, as shown in FIG. 13D. It is noted that the pattern of the doped region is determined according to the pattern of the periodic mask 61′. In other words, the periodic patterned structures 11″, 13″, and 15″ correspond to the pattern periodic mask 61′.

As disclosed above, the first portion 11A of the semiconductor layer 11 and the top view of the semiconductor layer 15 may be a rectangle as shown in FIG. 4B. In an embodiment of the disclosure, the periodic structure 11″ (and/or 15″) is formed on the four sides of the rectangular first portion 11A. In another embodiment of the disclosure, the periodic structure 11″ (and/or 15″) is only formed on the long side of the rectangular first portion 11A and not formed on the short side of the rectangular first portion 11A, so that the cost of forming the periodic structure 11″ (and/or 15″) on the short side of a rectangle is reduced. As the ratio of the long side vs. the short side of the rectangular first portion 11A grows bigger, the above method of forming the periodic structure 11″ (and/or 15″) on the long side of the rectangle saves more cost and makes the light extraction efficiency less likely to deteriorate.

So far, a process of manufacturing an LED is completed. The semiconductor layer 11 and/or a sidewall of the semiconductor layer 15 have a non-periodic or periodic patterned structure, such that full reflection is avoided and light extraction efficiency is increased. In some embodiments of the disclosure, the step of forming a non-periodic or periodic patterned structure does not damage the active layer 13, and element efficiency of the non-periodic or periodic patterned structure of the disclosure is superior to that of the generally known undercut structure.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A manufacturing method of a light emitting diode, comprising:
forming a first semiconductor layer, an active layer, and a second semiconductor layer sequentially on a substrate, wherein the first semiconductor layer and the second semiconductor layer have opposite conductivities;
forming a groove penetrating the second semiconductor layer, the active layer, and a part of the first semiconductor layer to define a stacked structure in-between the groove;
forming a planarization layer on the first semiconductor layer and the second semiconductor layer to fill up the groove;
forming a hard mask pattern on the planarization layer, wherein the hard mask pattern has a full mask area and a partial mask area corresponding to the groove;
performing an oblique ion implantation penetrating through the partial mask area to form a patterned doped region on a sidewall of the first semiconductor layer or on a sidewall of the second semiconductor layer;
removing the hard mask pattern and the planarization layer; and
removing the patterned doped region to form a patterned structure on the sidewall of the first semiconductor layer or on the sidewall of the second semiconductor layer.

2. The method of manufacturing the light emitting diode according to claim 1, wherein a width of the partial mask area is smaller than a width of the groove.

3. The method of manufacturing the light emitting diode according to claim 1, wherein a process of removing the patterned doped region comprises: inductively coupled plasma, reactive ion etching, wet etching, or a combination thereof.

4. The method of manufacturing the light emitting diode according to claim 1, wherein the partial mask area is a periodic mask, and the patterned structure is a periodic structure.

5. The method of manufacturing the light emitting diode according to claim 1, wherein the partial mask area is a non-periodic mask, and the patterned structure is a non-periodic structure.

6. The method of manufacturing the light emitting diode according to claim 5, wherein the step of forming the hard mask pattern on the planarization layer comprises:
forming a hard mask layer on the planarization layer;
patterning the hard mask layer to form the full mask area and expose the planarization layer corresponding to the groove;
forming a metal film on the full mask area and the exposed planarization layer;
tempering the metal film to form the non-periodic mask.

7. The method of manufacturing the light emitting diode according to claim 1, wherein a top view of the stacked structure is a rectangle having a long side and a short side, and the patterned structure is only located on the long side and not located on the short side.

8. The method of manufacturing the light emitting diode according to claim 1, wherein the step of performing the oblique ion implantation penetrating through the partial mask area further comprises forming the patterned doped region on a sidewall of the active layer; and
wherein the step of removing the patterned doped region further comprises forming the patterned structure on the sidewall of the active layer.

9. The method of manufacturing the light emitting diode according to claim 1, wherein an oblique angle of the oblique ion implantation forming the patterned doped region on the sidewall of the first semiconductor layer is between 5˜40°.

10. The of manufacturing the light emitting diode according to claim 1, wherein an oblique angle of the oblique ion implantation forming the patterned doped region on the sidewall of the second semiconductor layer is between 5˜40°.

11. The method of manufacturing the light emitting diode according to claim 1, wherein an oblique angle of the oblique ion implantation forming the patterned doped region on the sidewall of the first semiconductor layer is larger than an oblique angle of the oblique ion implantation forming the patterned doped region on the sidewall of the second semiconductor layer.

12. A light emitting diode, comprising:
a substrate;
a first semiconductor layer positioned on the substrate, wherein the first semiconductor layer has a first region and a second region, a thickness of the first region is larger than a thickness of the second region;
an active layer positioned on the first region of the first semiconductor layer;
a second semiconductor layer positioned on the active layer, wherein the first semiconductor layer and the second semiconductor layer have opposite conductivities; and
a patterned structure positioned on a sidewall of the first region of the first semiconductor layer or on a sidewall of the second semiconductor layer.

13. The light emitting diode according to claim 12, wherein the patterned structure is a periodic structure or a non-periodic structure.

14. The light emitting diode according to claim 12, wherein the patterned structure is further positioned on a sidewall of the active layer.

15. The light emitting diode according to claim 12, wherein a top view of the first region of the first semiconductor layer and the second semiconductor layer is a rectangle having a long side and a short side, and the patterned structure is only located on the long side only and not located on the short side.
